(19) United States
(12) Patent Application Publication
(10) Pub. No.: US 2003/0108803 A1
(43) Pub. Date: Jun. 12, 2003

(54) Method of manufacturing phase shift mask, phase shift mask and apparatus

(75) Inventor: Kazuyuki Maetoko, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/209,885

(22) Filed: Aug. 2, 2002

(30) Foreign Application Priority Data
Dec. 7, 2001 (JP) 2001-373666(P)

(51) Int. Cl. G03F 9/00; G03C 5/00

(52) U.S. Cl. 430/5; 430/322; 430/324; 430/394

(57) ABSTRACT

In a method of manufacturing a phase shift mask, after a phase shift layer forming step in which a phase shift layer is formed on a transparent substrate, a light shielding film forming step, in which a Cr film as a light shielding film is formed on an prescribed area on a phase shift layer, is performed. By employing the process, it is possible to provide a method of manufacturing a phase shift mask that enables finding defects produced in the phase shift layer at an early stage of the manufacturing process, a phase shift mask manufactured according to the manufacturing method thereof, and an apparatus manufactured by the same.

### BACKGROUND OF THE INVENTION

1. Field of the Invention

The present invention relates to a method of manufacturing a phase shift mask, and more specifically, to a method of manufacturing a phase shift mask that enables finding defects in a phase shift layer at an early stage, to a phase shift mask manufactured according to the manufacturing method thereof, and to an apparatus manufactured by the same.

2. Description of the Background Art

In recent years, a halftone phase shift mask, capable of providing a projected image of a fine scale, is increasingly applied to photomasks used for manufacturing semiconductor devices. The optimum transmissivity for the light source wavelength used in wafer lithography of a phase shift film of the halftone phase shift mask is to be 2 to 40%.

On the other hand, the halftone phase shift mask must be formed with a light shielding film of a single layer film of Cr or other metal film or metal silicide film, or a multilayer film of these materials, in order to prevent resist from being resolved by a light leaked from an adjacent chip incurred from an imprecise alignment of a reticle blind in a scanner, or being resolved elsewhere than a pattern by light that transmitted through a phase shift film in a chip on the reticle. In particular, it is an essential technique to form the light shielding film in the chip on the reticle when the transmissivity of the phase shift film of 9% or more is to be attained.

Now, referring to sectional views of FIGS. 16 to 25, an overview of first to tenth manufacturing steps of a method of manufacturing a phase shift mask according to a conventional technique will be described.

First, referring to FIG. 16, a phase shift layer 2 of a prescribed thickness is formed on a quartz substrate 1 as a transparent substrate, then a Cr film 10 of a prescribed thickness is formed thereon as a light shielding film, and then a resist film 13 is formed thereon. Thereafter, a prescribed area of the resist film 13 is exposed.

Next, referring to FIG. 17, the resist film 13 is developed to form an aperture 13h of a prescribed pattern. Thereafter, referring to FIG. 18, the Cr film 10 is patterned using resist film 13 as an etching mask to form an aperture 10h of a prescribed pattern.

Next, referring to FIG. 19, the phase shift layer 2 is patterned using the resist film 13 successively as an etching mask to form an aperture 2h of a prescribed shape. Thereafter, referring to FIG. 20, the resist film 13 is removed.

Next, referring to FIG. 21, a resist film 15 is applied so as to fill the apertures 2h and 10h as well as to cover the surface of the Cr film 10. Thereafter, referring FIG. 22, a prescribed area of the resist film 15 is exposed.

Next, referring to FIG. 23, the resist film 15 is developed to leave a resist film 15A on the Cr film 10 beside the aperture 10h, exposing portions of the surface of the Cr film 10. Thereafter, referring to FIG. 24, unnecessary portions of the Cr film 10 is removed by etching using the resist film 15A as a mask. Thereafter, referring to FIG. 25, the resist film 15A is removed to leave a Cr film 10A on the phase shift layer 2, exposing portions of the surface of the phase shift layer 2.

Thus, a halftone shift mask is completed, which includes a light transmissive area 100 exposing the surface of the quartz substrate 1, a phase shifter area 200 implemented by a phase shift layer 2 provided on the transparent substrate 1 for achieving a phase shift of 180 degrees against the exposing light passing through the light transmissive area as well as a transmissivity of 2 to 40%, and a light shielding area 300 implemented by a shielding film 10A provided on the prescribed area of the phase shift layer 2 for shielding the incident exposing light to the phase shift layer 2.

In the foregoing manufacturing method of the phase shift mask, however, the manufacturing process is performed with the phase shift layer 2 being covered by the Cr 10, thus defects can not be detected until the pattering of the Cr film 10A shown in FIG. 25 is finished. Accordingly, when defects are found in the phase shift layer 2, whole previous process will be wasted, thus increasing the wasteful time and hindering an early delivery and a saving of the manufacturing cost of the phase shift mask.

### SUMMARY OF THE INVENTION

The object of the present invention is to provide a manufacturing method of a phase shift mask which enables finding defects produced in a phase shift layer at an early stage, a phase shift mask manufactured according to the manufacturing method thereof, and an apparatus manufactured by the same.

The present invention provides a method of manufacturing a phase shift mask including a light transmissive area exposing the surface of the transparent substrate, a phase shifter area having a phase shift layer provided on the transparent substrate, and a light shielding area having a light shielding film shielding the incident exposing light provided on the phase shift layer, which method includes a phase shift layer forming step in which the phase shift layer is formed on the transparent substrate, and thereafter a light shielding film forming step in which a light shielding film is formed on the prescribed area on the phase shift layer is performed.

According to the method of manufacturing the phase shift mask, as the phase shift layer forming step is completed at the early stage of the manufacturing process, presence of any defect can be examined at this point. As a result, the wasteful time in case of any defect being found in the phase shift layer can be reduced compared to the conventional process, thus the early delivery and the saving of the manufacturing cost of the phase shift mask can be achieved.

In the present invention, in order to complete the phase shift layer forming step at the early stage of the manufacturing process, steps set forth below are employed in one aspect. The phase shift layer forming step includes a step of forming the phase shift layer on the transparent substrate, a step of forming a first resist film having a prescribed pattern on the phase shift layer, and a step of patterning the phase shift layer utilizing the first resist film, wherein the light shielding film forming step includes a step of forming a second resist film so as to cover the transparent substrate and the phase shift layer, a step of removing the second resist film from the area on the phase shift layer corresponding to the area on which the light shielding film should be left, a step of forming the light shielding film so as to cover the second resist film and the phase shift layer, and a step of removing the second resist film as well as the light shielding film positioned thereon through a lift-off method to leave the light shielding film only on the light shielding area on the phase shift layer.

Further, in the present invention, in order to complete the phase shift layer forming step at an early stage of the manufacturing process, steps set forth below are employed in another aspect. The phase shift layer forming step includes a step of forming a phase shift layer on the transparent substrate, a step of forming a first resist film having a prescribed pattern on the phase shift layer, and a step of patterning the phase shift layer utilizing the first resist film, wherein the light shielding film forming process includes a step of forming the light shielding film so as to cover the transparent substrate and the phase shift layer, a step of leaving the second resist film only on the area on the phase shift mask corresponding to the area on which the light shielding film should be left, and a step of removing only the exposed part of the light shielding film utilizing the second resist film as a mask to leave the light shielding film only on the light shielding area on the phase shift layer.

More preferably in the present invention, the light shielding film is formed of at lease one layer selected from the group consisting of a metal film, a metal oxide film, a metal oxide nitride film, and a metal oxide nitride carbide film.

More preferably in the present invention, the light shielding film is further preferably of at lease one layer selected from the group consisting of a metal silicide film, a metal silicide oxide film, a metal silicide oxide nitride film, and a metal silicide oxide nitride carbide film.

The present invention provides a phase shift mask including a light transmissive area exposing the surface of the transparent substrate, a phase shifter area having a phase shift layer provided on the transparent substrate, and a light shielding area having a light shielding film shielding the incident exposing light provided on the phase shift layer, wherein after forming the phase shift layer on the transparent substrate, a light shielding film is provided on the prescribed area on the phase shift layer. Further, an apparatus according to the present invention is preferably manufactured utilizing the phase shift mask of the present invention.

When devices such as semiconductor devices are manufactured using the phase shift mask manufactured according to the present method, unsatisfactory exposure decreases in the manufacturing step, thus improved production yield in the manufacturing step of the device can be achieved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 9 are cross-sectional views showing first to ninth manufacturing steps of a method of manufacturing a phase shift mask in a first embodiment according to the present invention.

FIGS. 10 to 15 are cross-sectional views showing fifth to tenth manufacturing steps of a method of manufacturing a phase shift mask in a second embodiment according to the present invention.

FIGS. 16 to 25 are cross-sectional views showing first to tenth manufacturing steps of a method of manufacturing a phase shift mask according to the conventional technique.

### DESCRIPTION OF THE PREFERRED EMBODIMENTS

Referring to the figures, a method of manufacturing a phase shift mask in each of the embodiments according to the present invention will be described below.

First Embodiment

Manufacturing Method

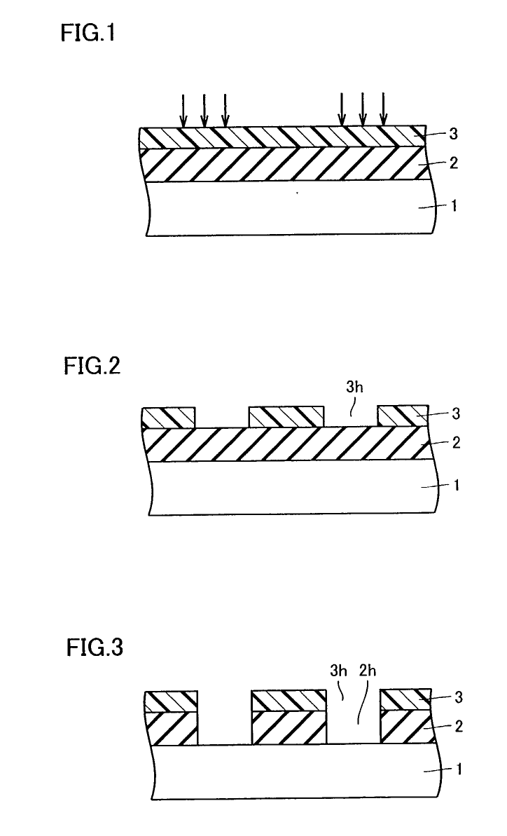

First, referring to FIGS. 1 to 9, a method of manufacturing a phase shift mask in the present embodiment will be described.

Referring to FIG. 1, a phase shift layer 2 of a prescribed thickness is formed on a quartz substrate 1 as a transparent substrate, then a first resist film 3 is formed thereon. Thereafter, a prescribed area of the first resist film 3 is exposed. When using an electron beam lithography system in the exposure of the first resist film 3, a conductive layer is formed on the first resist film 3 in advance (not shown). When using a laser lithography system, the conductive layer need not be formed on the first resist film 3.

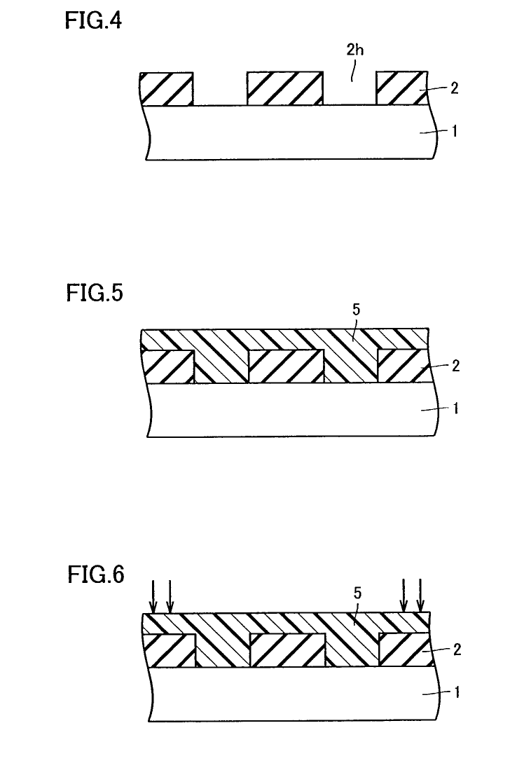

Referring to FIG. 2, the first resist film 3 is developed to form an aperture 3h of a prescribed pattern. Thereafter, referring to FIG. 3, the phase shift layer 2 is patterned using the first resist film 3 as an etching mask to form an aperture 2h of a prescribed shape. Thereafter, referring to FIG. 4, the first resist film 3 is removed. Thus, the phase shift layer forming step is completed.

Referring to FIG. 5, a second resist film 5 is applied so as to fill the aperture 2h and to coat the surface of the phase shift layer 2. Thereafter, referring to FIG. 6, a prescribed area of the second resist film 5 is exposed. When using an electron beam lithography system in the exposure of the second resist film 5, a conductive layer is formed on the second resist film 5 in advance (not shown). When using a laser lithography system, the conductive layer need not be formed on the second resist film 5.

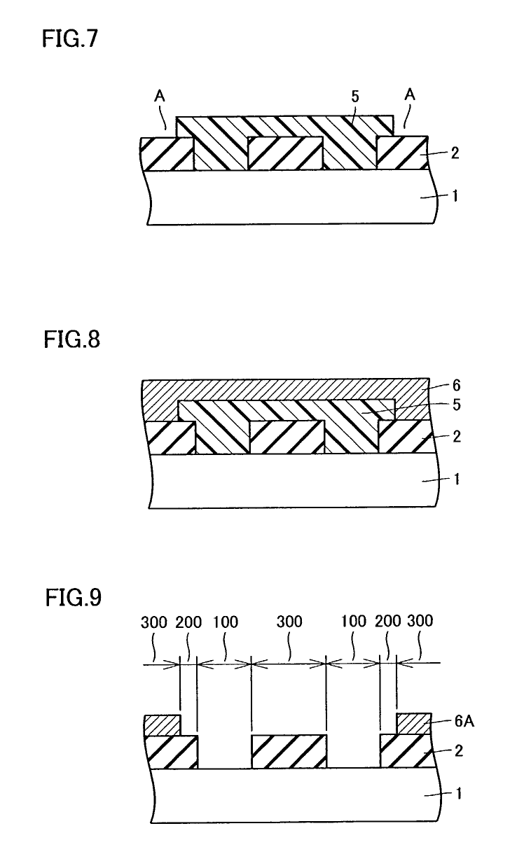

Referring to FIG. 7, the second resist film 5 is exposed, leaving the second resist film 5 so as to form, on the phase shift layer 2 beside of the aperture 2h, an area (A) exposing a portion of the surface of the phase shift layer 2.

Referring to FIG. 8, Cr film 6 of a prescribed thickness as a light shielding film is formed so as to cover the second resist film 5 and the phase shift layer 2. Here, the film is not limited to the Cr film, and it may be a film selected from the group consisting of other metal film having a capability for shielding light, a metal oxide film, a metal oxide nitride film, and a metal oxide nitride carbide film, or a multilayer of more than two films selected appropriately from the aforementioned group of films. Further, it may be a film selected from a metal silicide film, a metal silicide oxide film, a metal silicide oxide nitride film, and a metal silicide oxide nitride carbide film, or a multilayer of more than two films selected appropriately from the aforementioned group of films.

Referring to FIG. 9, the second resist film 5 and the Cr film 6 positioned thereon are removed by the lift-off method to leave Cr film 6A in the prescribed area of the phase shift layer 2. Thus, the light shielding film formation step is completed.

Structure of Phase Shift Mask

Thus, a halftone phase shift mask is completed, which includes a light transmissive area 100 exposing the surface of the quartz substrate 1 exposed, a phase shifter area 200 having a phase shift layer 2 provided on the transparent substrate 1 for achieving a phase shift of 180 degrees against the exposing light passing through the light transmissive area as well as a transmissivity of 2 to 40%, and a light shielding area 300 having a light shielding film 6A provided on the prescribed area on the phase shift layer 2 for shielding the incident exposing light into the phase shift layer 2.

Effects of the Invention

Thus, according to the method of manufacturing the phase shift mask in the present embodiment, as the phase shift layer forming step is completed at the early stage of the manufacturing process, presence of any defect can be examined at this point. As a result, the wasteful time in case of any defect being found in the phase shift layer 2 can be reduced compared to the conventional process, thus the early delivery and the saving of the manufacturing cost of the phase shift mask can be achieved.

Additionally, in the step shown in FIG. 9, although the step of leaving Cr film 6A only in the prescribed area of the phase shift layer 2 by the lift-off method is employed, it is possible to employ another step after the step shown in FIG. 8, in which the Cr film 6 is polished by CMP method until the surface of the second resist film 5 is exposed, then only the second resist film 5 is removed by etching or the like to leave the Cr film 6A in the prescribed area of the phase shift layer 2.

Second Embodiment

Manufacturing Method

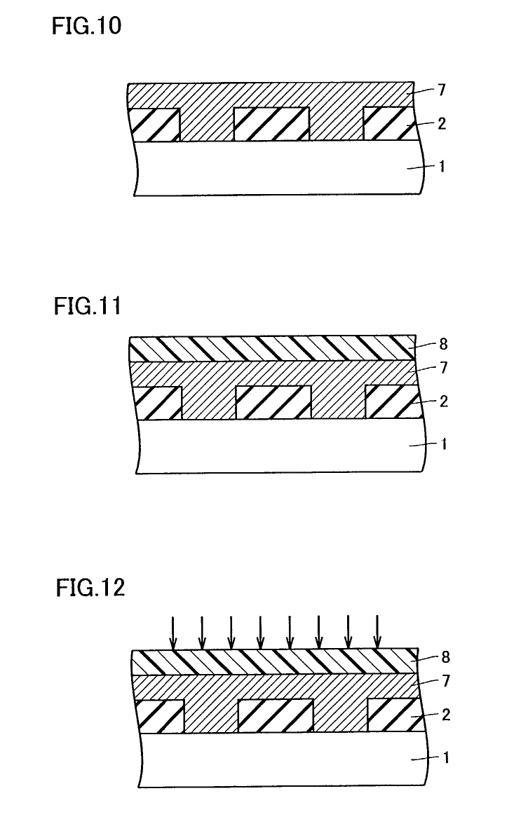

First, referring to FIG. 10 to 15, a method of manufacturing a phase shift mask in the present embodiment will be described. Since the phase shift layer forming steps are similar to those described with reference to FIGS. 1 to 4 of the first embodiment, descriptions of the first to the fourth steps will not be repeated and will be given to the fifth and the following steps.

Referring to FIG. 10, after completing the formation of the phase shift layer 2, Cr film 7 of the prescribed thickness of the light shielding film is formed so as to fill the aperture 2h and to cover the surface of the phase shift layer 2. The film is not limited to the Cr film and it may be a film selected from the group consisting of other metal film having a capability for shielding light, a metal oxide film, a metal oxide nitride film, and a metal oxide nitride carbide film, or a multilayer of more than two films selected appropriately from the aforementioned group of films. Further, it may be a film selected from a metal silicide film, a metal silicide oxide film, a metal silicide oxide nitride film, and a metal silicide oxide nitride carbide film, or a multilayer of more than two films selected appropriately from the aforementioned films. Thereafter, referring to FIG. 11, the second resist film 8 is formed on the Cr film 7.

Referring to FIG. 12, the prescribed area of the second resist film 8 is exposed. When an electron beam lithography system is used in the exposure of the second resist film 8, a conductive layer is formed on the second resist film 8 in advance (not shown). When using a laser lithography system, the conductive layer need not be formed on the second resist film 8 beforehand. Thereafter, referring to FIG. 13, the second resist film 8 is developed, leaving the second resist film 8A in the prescribed position on the Cr film 7.

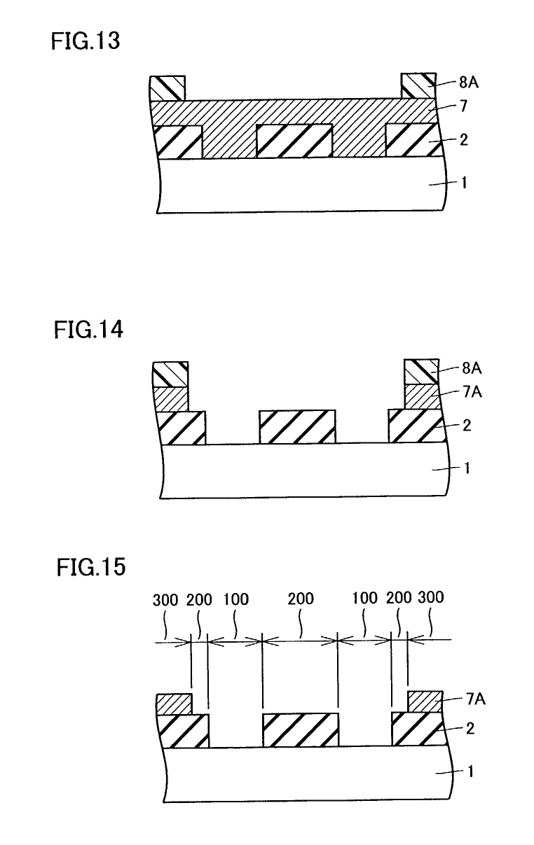

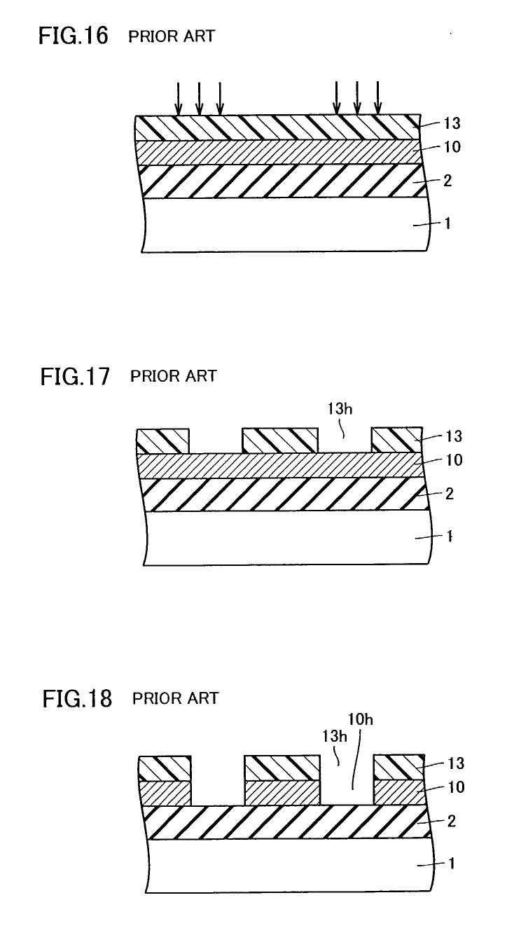

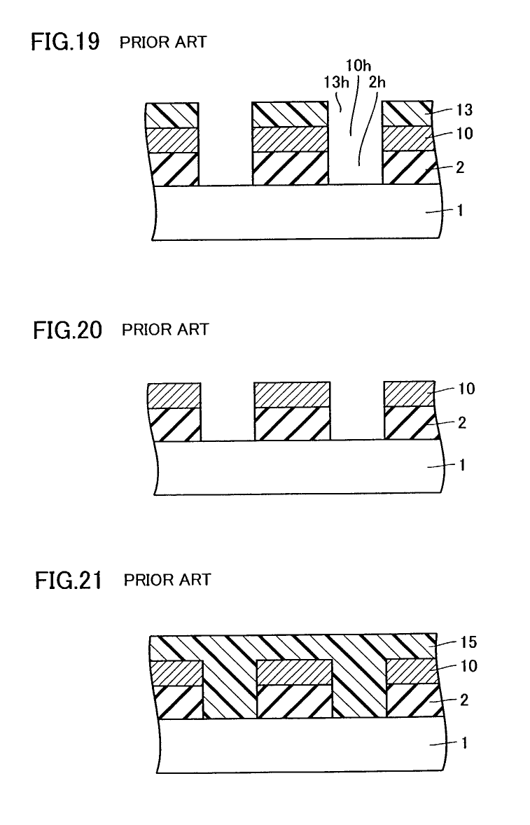

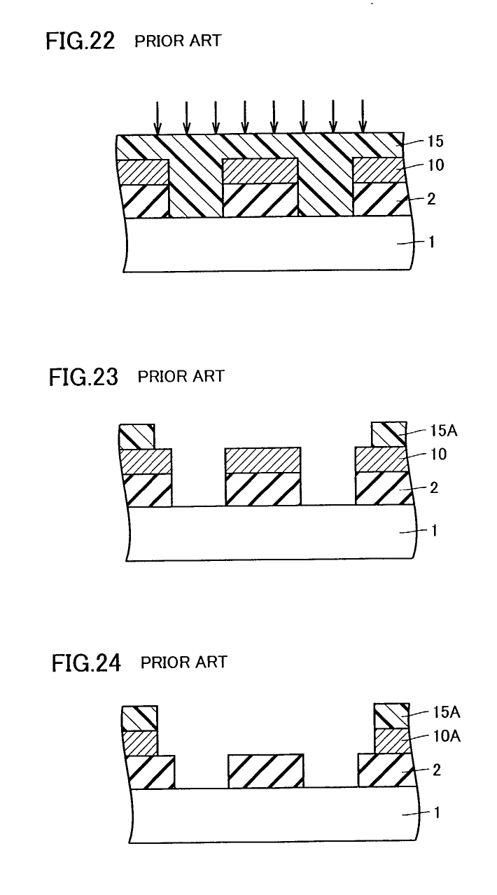

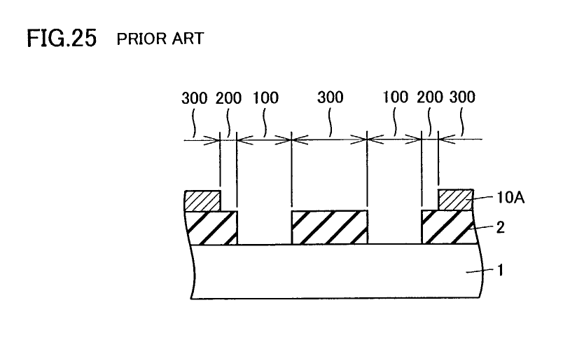

Referring to FIG. 14, Cr film 7 is removed by etching to leave Cr film 7A on the prescribed area of the phase shift layer 2. Thus, the light shielding film forming step is completed.

Structure of Phase Shift Mask

Thus, a halftone phase shift mask is completed, which includes a light transmissive area 100 exposing the surface of the quartz substrate 1 exposed, a phase shifter area 200 having a phase shift layer 2 provided on the transparent substrate 1 for achieving a phase shift of 180 degrees against the exposing light passing through the light transmissive area as well as a transmissivity of 2 to 40%, and a light shielding area 300 having a shielding film 7A provided on the prescribed area on the phase shift layer 2 for shielding the incident exposing light into the phase shift layer 2.

Effects of the Invention

Thus, according to the present embodiment of the manufacturing method of the phase shift mask, as the phase shift layer forming step is completed at the early stage of the manufacturing process as in the first embodiment, presence of any defect can be examined at this point. As a result, the wasteful time in case of any defect being found in the phase shift layer can be reduced compared to the conventional process, thus the early delivery and the saving of the manufacturing cost of the phase shift mask can be achieved.

When devices such as semiconductor devices are manufactured using the phase shift mask manufactured according to the present method, unsatisfactory exposure decreases in the manufacturing step, thus improved production yield in the manufacturing step of the device can be achieved. In particular, it can be used advantageously in semiconductor devices such as DRAM, SRAM, ERAM, flash memory, ASIC, microcomputer, GaAs or the like. It can also be applied to a single semiconductor device or a device such as liquid display apparatus other than a semiconductor device.

Through the method of manufacturing the phase shift mask according to the present invention, as the phase shift layer forming step is completed at the early stage of the manufacturing process, presence of any defect can be examined at this early stage. As a result, the wasteful time in case of any defect being found in the phase shift layer can be reduced compared to the conventional process, thus the early delivery and the saving of the manufacturing cost of the phase shift mask can be achieved.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a phase shift mask including
a light transmissive area exposing a surface of a transparent substrate,
a phase shifter area having a phase shift layer provided on said transparent substrate, and
a light shielding area provided on the prescribed area on said phase shift layer, having a light shielding film shielding incident exposing light to said phase shift layer; said method comprising
a phase shift layer forming step in which the phase shift layer is formed on said transparent substrate, followed by a light shielding film forming step in which the light shielding film is formed on the prescribed area on said phase shift layer.

2. The method of manufacturing a phase shift mask according to the claim 1, wherein
said phase shift layer forming step includes
a step of forming the phase shift layer on said transparent substrate,
a step of forming the first resist film having a prescribed pattern on said phase shift layer, and
a step of patterning said phase shift layer by said first resist film;
said light shielding film forming step includes
a step of forming the second resist film so as to cover said transparent substrate and said phase shift mask layer,
a step of removing said second resist film only from an area on said phase shift layer corresponding to the area on which said light shielding film is to be left,
a step of forming said light shielding film so as to cover said second resist film and said phase shift layer, and
a step of removing said second resist film and said light shielding film positioned thereon by lift-off method to leave said light shielding film only on said light transmissive area on said phase shift layer.

3. The method of manufacturing a phase shift mask according to the claim 1, wherein
said phase shift layer forming step further includes
a step of forming the phase shift layer on said transparent substrate,
a step of forming a first resist film having a prescribed pattern on said phase shift layer, and
a step of patterning said phase shift layer by said first resist film;
said light shielding film forming step further includes
a step of forming said light shielding film so as to cover said transparent substrate and said phase shift layer,
a step of leaving the second resist film only on an area corresponding to an area on said phase shift layer to which said light shielding film is to be left, and
a step of removing exposed said light shielding film only by using said second resist film as a mask to leave said light shielding film only on said light shielding area on said phase shift layer.

4. The method of manufacturing a phase shift mask according to the claim 1, wherein
said light shielding film is at least one layer of film selected from the group consisting of a metal layer, a metal oxide layer, a metal oxide nitride layer, and a metal oxide nitride carbide layer.

5. The method of manufacturing a phase shift mask according to the claim 1, wherein
said light shielding film is at least one layer of film selected from the group consisting of a metal silicide layer, a metal silicide oxide layer, a metal silicide oxide nitride layer, and a metal silicide oxide nitride carbide layer.
